(19) United States
(12) Patent Application Publication
(10) Pub. No.: US 2023/0418141 A1
(43) Pub. Date: Dec. 28, 2023

(54) Device and a Method for Powering Laser Projectors

(71) Applicant: INUITIVE LTD., Ra'anana (IL)

(72) Inventors: Mishel IVGI, Yehud-Monoson (IL); Michael GERMAN, Modiin (IL)

(21) Appl. No.: 17/850,490

(22) Filed: Jun. 27, 2022

(51) Int. Cl. G03B 21/20; H01S 5/068; H01S 5/0683

(52) U.S. Cl. CPC G03B 21/2033; H01S 5/06808; H01S 5/06835

(57) ABSTRACT

An arrangement and a method are provided, wherein the arrangement is configured to prevent current pulses from reaching a laser diode, wherein the arrangement is configured to receive voltage required for its operation from a USB power source, and wherein the arrangement comprises: a capacitor configured to provide energy for the operation of the laser diode at times when high current pulses are required by a camera associated with the arrangement; a software configurable micro controller, operative to control functionality of the arrangement so as to prevent current pulses from reaching the laser diode; and a current source configured to provide current for the operation of the laser diode under safe conditions and to cease provisioning of that current when conditions are unsafe for the operation of the laser diode.

### TECHNICAL FIELD

The present disclosure generally relates to the field of optics, and more particularly, it relates to the operation of laser projectors.

### BACKGROUND

A laser projector for 3D sensing application is a device that projects a static laser image on any scene to create an image for entertainment or professional use. It consists of a housing that contains lasers, Diffractive Optic Element (DOE), mirrors, beam splitters, Collimators, and other optical components. A laser projector can contain one laser light source for single-color projection or three sources for RGB (red, green, and blue) full color projection.

Power control for the laser diodes or for a vertical-cavity surface-emitting laser (“VCSEL”) array is typically performed by automatically adjusting the power source to save power and minimize heat dissipation. They contain various protection circuits, such as laser diode or VCSEL array overcurrent and short detection, Duty cycle limitation, thermal shutdown, overcurrent detection and photodiode optical power detection circuit.

In the recent years, many of the laser projecting systems are connected to USB outputs that are used to provide power supply to the projecting system. However, such systems that are connected to a USB output (e.g., of a cellular telephone), are current restricted, and the upper current threshold of a standard USB3.x port is 900 mA.

However, one of the problems associated with such systems is that at the beginning of the illumination (e.g., at the beginning of a frame) there is a substantial increase in the instantaneous current consumption of the projector (i.e., a too high current pulse), to a level that exceeds the allowable current level from the USB power supply.

There were some attempts made in the past in which a capacitor was added to the system, still, in the solutions known in the art, but these solutions are rather limited and cannot provide a solution to the problem of preventing the high pulse from reaching the projector when the capacitor voltage is low. Consequently, there is a need to add a separate safety circuit, and as these solutions are hardware based, they do not provide any flexibility in the operation of the system (i.e., these solutions are not configurable).

The present disclosure seeks to provide a solution to these problems.

### SUMMARY OF THE DISCLOSURE

The disclosure may be summarized by referring to the appended claims.

It is an object of the present disclosure to provide an arrangement and a method for preventing high current pulses from reaching one or more laser diodes of a projecting module.

Other objects of the present invention will become apparent from the following description.

According to an embodiment of the disclosure, there is provided an arrangement configured to prevent current pulses from reaching one or more laser diodes of a projecting module, wherein the arrangement is configured to receive voltage required for its operation via a USB power source (e.g., 5 v), wherein the arrangement comprises:
a capacitor configured to provide energy for the operation of the one or more laser diodes at times when high current pulses are required by a device associated with the arrangement;
a software configurable micro controller, operative to control functionality of the arrangement so as to prevent current pulses from reaching the one or more laser diodes; and
a current source configured to provide current for the operation of the one or more laser diodes under safe conditions and to cease provisioning of that current when conditions are unsafe for the operation of the one or more laser diodes.

According to another embodiment of the present disclosure, the capacitor is configured to store energy at at least 15V.

In accordance with another embodiment of the present disclosure, the software configurable micro controller is managed by a software embedded in a device operative outside the arrangement.

By yet another embodiment of the present disclosure, upon receiving a requirement for illumination of a target by the one or more laser diodes that is associated with a necessary high current pulse in order to fulfill that requirement, the micro controller is configured to fulfill the requirement by drawing energy from the capacitor and to prevent receiving energy from the USB power source, thereby preventing the arrangement from being exposed to the high current pulse.

According to still another embodiment the capacitor is configured to be charged during a period that extends between two consecutive current pulses.

In accordance with another embodiment of the disclosure, upon detecting by the micro controller that the instantaneous energy level at the capacitor has dropped down to a pre-defined lower threshold, the current source is prevented form providing energy to the one or more laser diodes.

By still another embodiment of the present disclosure, the instantaneous capacitor's voltage level is monitored by the micro controller.

According to yet another embodiment of the disclosure, the instantaneous power derived from the USB power source is provided at a current level that is substantially less than 900 mAmp (or another applicable current limit of the USB port), and wherein the micro controller is configured to affect transient changes in the current level.

In accordance with another aspect of the disclosure there is provided a method for preventing current pulses from reaching an operating projecting module, wherein the method comprises the steps of:
(i) provisioning of energy from a USB power source for operating one or more laser diode or a VCSEL array;
(ii) drawing energy from the energy received from the USB power source to be used for charging a capacitor;
(iii) upon detecting an instantaneous demand of energy for powering the one or more laser diodes would lead to a requirement that involves a current pulse, the requirement for energy will be fulfilled by drawing voltage from the capacitor; and
(iv) upon fulfilling the instantaneous energy demand that involves the current pulse, re-charging the capacitor by using energy received from the USB power source.

By yet another embodiment of this aspect of the disclosure, the method further comprising a step by which:
(v) upon detecting that the capacitor's voltage has reached a lower threshold, disabling current supply to the one or more laser diodes.

### BRIEF DESCRIPTION OF TUE DRAWINGS

For a more complete understanding of the present invention, reference is now made to the following detailed description taken in conjunction with the accompanying drawings wherein:

FIG. 1—illustrates a schematic diagram of a system construed in accordance with an embodiment of the present invention, for preventing current pulses from reaching an operating projecting module; and

FIG. 2—illustrates a flow chart of a method for carrying out an embodiment construed in accordance with the present invention.

### DETAILED DESCRIPTION

In this disclosure, the term “comprising” is intended to have an open-ended meaning so that when a first element is stated as comprising a second element, the first element may also include one or more other elements that are not necessarily identified or described herein or recited in the claims.

In the following description, for the purposes of explanation, numerous specific details are set forth in order to provide a better understanding of the present invention by way of examples. It should be apparent, however, that the present invention may be practiced without these specific details.

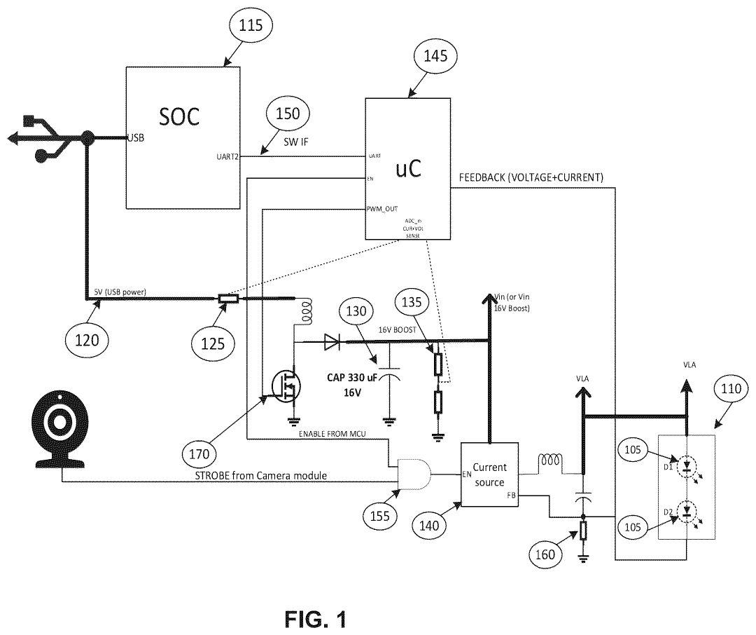

FIG. 1 illustrates a schematic diagram of an arrangement 100 construed in accordance with an embodiment of the present invention, which is configured to prevent excessive current pulses from reaching laser diodes 105 comprised in projecting module 110.

The arrangement comprises according to this example a module comprising a multi-core system on chip 115 that supports high-quality 3D depth vision.

Module 115 comprises a USB socket being a SV power source 120 which is configured to provide power required for the operation of arrangement 100. The current drawn from power source 120 passes current sensing resistor 125 and continues partially towards capacitor 130 and partially towards power laser diodes 105 via current source 140. Capacitor 130 is used to store energy at a high voltage, and one example of such a capacitor is a 300-400 μF capacitor that stores energy at 16V. Arrangement 100 further comprises micro controller 145 which is responsible for the operation of arrangement 100 and is managed by the multi-core system on chip 115 via software interface 150. In addition, transistor 170 that functions as a DC/DC boost convertor, is triggered by micro controller 145 and is operated by a Pulse Width Modulation (“PWM”) signal generated by micro controller 145, which changes the duty cycle of the PWM pulse, according to the current measured on sensing resistor 125 and the capacitor voltage as measured by resistor network 135.

At the beginning of a frame, a request for power is initiated by a camera module associated with arrangement 100, by which projecting module 110 is required to illuminate the scene by laser diodes 105. If there is such an illumination requirement from the camera the value of “1” reaches AND gate 155 from the camera, and if micro controller 145 receives information that relates to the incoming current using resistor 125, and to the outgoing current measured on resistor 160 and resistor network voltage 135, wherein the received information allows the micro controller to enable the discharge of capacitor 130. In such a case, the value “1” is sent from micro controller 145 to the AND gate 105, so that current source 140 will provide laser diodes 110 with the required pulse energy derived from the energy stored at capacitor 130, thereby preventing the arrangement from being exposed to a too high current pulse to the projecting module 110 and also prevents a high current pulse from being drawn from the USB source 120.

As soon as capacitor 130 has provided the required pulse energy for the operation of laser diodes 105, laser diodes receive the current required for their operation from USB power source 120 as well as capacitor 130 begins its charging, preferably under constant current, using USB power source 120. If the arrangement operates at a rate of say, 30 frames per second, i.e., 33 msec per frame, then the energy is required for each pulse at the beginning of a frame (e.g., at the first 7 msec), while for the rest of each of the frames, no energy would be required from capacitor 130, thereby allowing the capacitor to be charged during the remaining time of the respective frame.

As mentioned above, the control of the arrangement is done by micro controller 145, so as soon as micro controller 145 detects through resistors 135 that the energy at capacitor 130 drops down to a pre-defined lower threshold e.g., 5-6 volts, the current that is being transferred to the laser diodes 105 might cause shutdown of the arrangement due to current limit policy of the USB power source 120. In order to avoid such a scenario, when micro controller 145 detects a decrease at the capacitor energy level to the threshold level, it issues a disable signal (“0”) to gate 155. Consequently, the output of gate 155 will be “0” which in turn disables current source 140 so that no energy will be provided to laser diodes 105 via current source 140.

In addition to the above, micro controller 145 is further configured to measure the energy transferred to monitor the product of pulse width and current level (P=T*I) during which current source 140 may supply the energy to laser diodes 105 (i.e., exposure time) by monitoring the voltage on sensing resistor 160, which can be for example 6-8 msec and 1-2 A. Once the P level reaches its maximum pre-defined level, micro controller 145 issues a disable signal (“0”) to gate 155. Consequently, the output of gate 155 will be “0” which in turn disables current source 140 so that no energy will be provided to laser diodes 105 via current source 140.

In addition, micro controller 145 is further configured to determine the energy (E) transferred to module 115 (and consequently to laser diodes 105) by monitoring the voltage V on the sensing resistor 160, and by applying the exposure time, the time that has lapsed since the beginning of provisioning the current, E is derived by utilizing the following relationship: E=T*P=T*(V\hat{ }2/R). This way, micro controller 145 is aware of the supplied power, which in turn is used in controlling the power provisioning to the laser diodes 105.

Preferably, throughout the operation of the arrangement, the voltage of the capacitor is monitored, in order to evaluate the capacitor's instantaneous voltage level.

In addition, USB socket 120 is able to provide the voltage with up to 900 mAmp current. However, according to an embodiment of the invention, this current level is configurable by the arrangement and operates at a lower current level (say 300 mAmp), while the difference between maximum level and the lower level may be changed in accordance with the arrangement requirement by using micro controller 145, thereby achieving control of the current drawn from power source 120, and if a problem is detected in any of the components described above, power source 120 may easily be disabled.

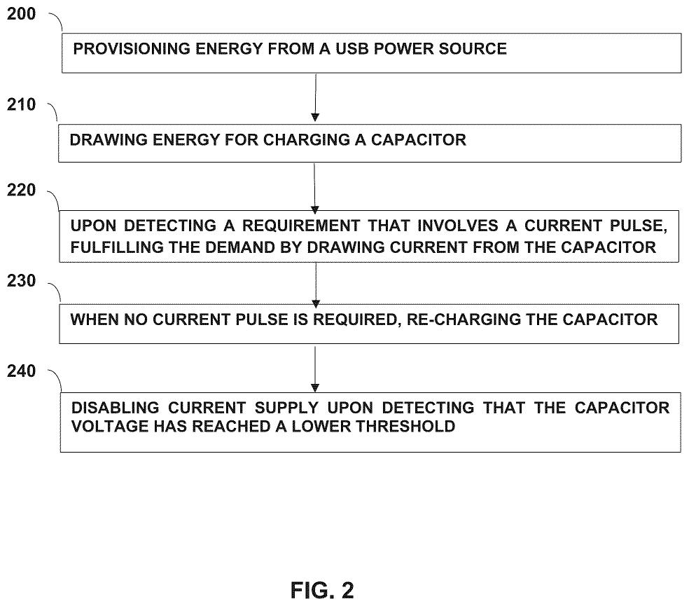

FIG. 2 illustrates a flow chart of a method for carrying out an embodiment construed in accordance with the present invention.

According to this embodiment, the method for preventing current pulses from reaching an operating projecting module begins with a step of providing energy for the operation of the projecting module's laser diodes from a USB power source (step 200). The energy received is used to power the laser diodes as well as to charge a capacitor (step 210). As soon as a micro controller detects that the instantaneous demand to power the laser diodes would lead to a requirement that involves a current pulse, this requirement will be fulfilled by drawing current from the charged capacitor (step 220). Once the requirement that involves a current pulse is no longer applicable, the capacitor starts its re-charging (step 230). If at any stage, the micro controller detects that the capacitor voltage has reached a lower threshold, the micro controller disables the current supply to the laser diodes (step 240).

In the description and claims of the present application, each of the verbs, “comprise” “include” and “have”, and conjugates thereof, are used to indicate that the object or objects of the verb are not necessarily a complete listing of members, components, elements or parts of the subject or subjects of the verb.

The present invention has been described using detailed descriptions of embodiments thereof that are provided by way of example and are not intended to limit the scope of the invention in any way. The described embodiments comprise different objects, not all of which are required in all embodiments of the invention. Some embodiments of the present invention utilize only some of the objects or possible combinations of the objects. Variations of embodiments of the present invention that are described and embodiments of the present invention comprising different combinations of features noted in the described embodiments will occur to persons of the art. The scope of the invention is limited only by the following claims.

1. An arrangement configured to prevent current pulses from reaching one or more laser diodes of a projecting module, wherein said arrangement is configured to receive voltage required for its operation via a USB power source, wherein said arrangement comprises:
a capacitor configured to provide energy for the operation of said one or more laser diodes at times when high current pulses are required by a device associated with said arrangement;
a software configurable micro controller, operative to control functionality of said arrangement so as to prevent current pulses from reaching said one or more laser diodes; and
a current source configured to provide current for the operation of said one or more laser diodes under safe conditions and to cease provisioning of that current when conditions are unsafe for the operation of said one or more laser diodes.

2. The arrangement of claim 1, where said capacitor is configured to store energy at at least 15V.

3. The arrangement of claim 1, wherein said software configurable micro controller is managed by a software embedded in a device operative outside said arrangement.

4. The arrangement of claim 1, wherein upon receiving a requirement for illumination of a target by the one or more laser diodes that is associated with a necessary high current pulse in order to fulfill that requirement, said micro controller is configured to fulfill said requirement by drawing energy from said capacitor and to prevent receiving energy from said USB power source, thereby preventing the arrangement from being exposed to said high current pulse.

5. The arrangement of claim 1, wherein said capacitor is configured to be charged during a period that extends between to consecutive current pulses.

6. The arrangement of claim 1, wherein upon detecting by said micro controller that the instantaneous energy level at said capacitor has dropped down to a pre-defined lower threshold, said current source is prevented form providing energy to the one or more laser diodes.

7. The arrangement of claim 1, wherein the instantaneous capacitor's voltage level is monitored by said micro controller.

8. The arrangement of claim 1, wherein the instantaneous power derived from said USB power source is provided at a current level that is substantially less than 900 mAmp, and wherein said micro controller is configured to affect transient changes in said current level.

9. A method for preventing current pulses from reaching an operating projecting module, wherein said method comprises the steps of:
(i) provisioning of energy from a USB power source for operating one or more laser diodes of said projecting module;
(ii) drawing energy from the energy received from the USB power source to be used for charging a capacitor;
(iii) upon detecting that an instantaneous demand of energy for powering said one or more laser diodes would lead to a requirement that involves a current pulse, fulfilling that instantaneous demand by drawing voltage from said capacitor; and
(iv) upon fulfilling the instantaneous energy demand that involves the current pulse, re-charging said capacitor by using energy received from the USB power source.

10. The method of claim 9. Further comprising a step that:
(v) upon detecting that said capacitor's voltage has reached a lower threshold, disabling current supply to the one or more laser diodes.
